(19) United States
(12) Patent Application Publication
(10) Pub. No.: US 2012/0175725 A1
(43) Pub. Date: Jul. 12, 2012

(54) SEMICONDUCTOR STORAGE DEVICE AND MANUFACTURING METHOD THEREOF

(75) Inventor: Hideto TAKEKIDA, Nagoya-shi (JP)

(73) Assignee: KABUSHIKI KAISHA TOSHIBA, Tokyo (JP)

(21) Appl. No.: 13/336,255

(22) Filed: Dec. 23, 2011

(30) Foreign Application Priority Data
Jan. 6, 2011 (JP) 2011-001354

(51) Int. Cl. H01L 27/04; H01L 21/762

(52) U.S. Cl. 257/499; 438/424; 257/E27.01; 257/E21.546

(57) ABSTRACT

A semiconductor storage device according to an embodiment includes a memory cell array provided on a semiconductor substrate and comprising a plurality of memory cells configured to store data therein, and a peripheral circuit part provided on the semiconductor substrate and configured to control the memory cell array. An element isolation part is provided between active areas where the memory cells and the peripheral circuit part are formed. A sidewall film is provided on a side surface of the active area in the peripheral circuit part.

### CROSS REFERENCE TO RELATED APPLICATIONS

This application is based upon and claims the benefit of priority from the prior Japanese Patent Application No. 2011-1354, filed on Jan. 6, 2011, the entire contents of which are incorporated herein by reference.

### FIELD

The embodiments of the present invention relate to a semiconductor storage device and a manufacturing method thereof.

### BACKGROUND

A NAND flash EEPROM (Electrically Erasable and Programmable Read Only Memory) has been known as a nonvolatile semiconductor storage device that is capable of electrical rewriting and high integration. The NAND flash EEPROM includes a memory cell array region having a plurality of memory cells capable of storing data therein and a peripheral circuit region for controlling memory cell arrays. STI (Shallow Trench Isolation) is provided as an element isolation part between memory cells adjacent to each other in a word line direction. In the peripheral circuit region, the STI is also provided between adjacent elements (for example, transistors) and between adjacent wells.

A trench of STI is formed by depositing a material for a tunnel dielectric film and a material for a floating gate on a semiconductor substrate, and then subsequently etching the material for a floating gate, the material for a tunnel dielectric film, and the semiconductor substrate. A planar layout of the trench of STI includes a fine pattern (several tens of nanometers) in the memory cell array region and a relatively large pattern (several hundreds of nanometers to several micrometers) in the peripheral circuit region, and these patterns are formed simultaneously. Accordingly, because of a density difference in shape between the memory cell array and the peripheral circuit region, a difference in depth of STI is easily generated between the memory cell array and the peripheral circuit region.

A high voltage as high as about 20 V is used for writing in a NAND flash memory. A transistor and a capacitor for generating and transmitting such a high voltage need to have a high breakdown voltage. To have these transistor and capacitor as a high breakdown voltage type, a gate dielectric film needs to be formed thicker than a tunnel dielectric film of a memory cell. At the time of processing the trench of STI, a difference in depth of the trench of STI is easily generated between the memory cell array region and the peripheral circuit region also because of a difference in thickness between the gate dielectric film and the tunnel dielectric film. In this case, the depth of the trench of STI in the peripheral circuit region with a low density of STI is deeper than that of the trench of STI in the memory cell array region. Therefore, a micro-trench shape may be formed at a boundary between a side surface and a bottom surface of the trench in the peripheral circuit region.

The micro-trench shape is a concavity (or a hollow) at the boundary between the side surface and the bottom surface of the trench. The micro-trench shape not only deteriorates the covering property of a silicon oxide film to be deposited later but also causes concentration of a stress caused by the silicon oxide film. A larger amount of silicon oxide film is used for STI in the peripheral circuit region than that for STI in the memory cell array region. Therefore, a stress applied to STI in the peripheral circuit region is larger than that applied to STI in the memory cell array region. Therefore, defects are generated with a high possibility in the peripheral circuit region in a subsequent thermal treatment.

### BRIEF DESCRIPTION OF THE DRAWINGS

FIG. 1 shows a configuration of a semiconductor storage device according to a first embodiment;

FIG. 2 is a cross-sectional view of a memory along an extending direction of the bit line BL;

FIGS. 3A to 3C are cross-sectional views of a memory cell array region and a peripheral circuit region along an extending direction of the word line WL;

FIGS. 4A to 7C are cross-sectional views of a manufacturing method of a memory according to the first embodiment;

FIG. 8A is a cross-sectional view of the memory cell MC;

FIG. 8B is a cross-sectional view of the low-breakdown voltage transistor TLV in the peripheral circuit region;

FIG. 8C is a cross-sectional view of the high-breakdown voltage transistor THV in the peripheral circuit region; and

FIGS. 9A to 9C are cross-sectional views of a manufacturing method of a memory according to the second embodiment.

### DETAILED DESCRIPTION

A semiconductor storage device according to an embodiment comprises a memory cell array provided on a semiconductor substrate and comprising a plurality of memory cells configured to store data therein, and a peripheral circuit part provided on the semiconductor substrate and configured to control the memory cell array. An element isolation part is provided between active areas where the memory cells and the peripheral circuit part are formed. A sidewall film is provided on a side surface of the active area in the peripheral circuit part.

Embodiments will now be explained with reference to the accompanying drawings. The present invention is not limited to the embodiments.

### First Embodiment

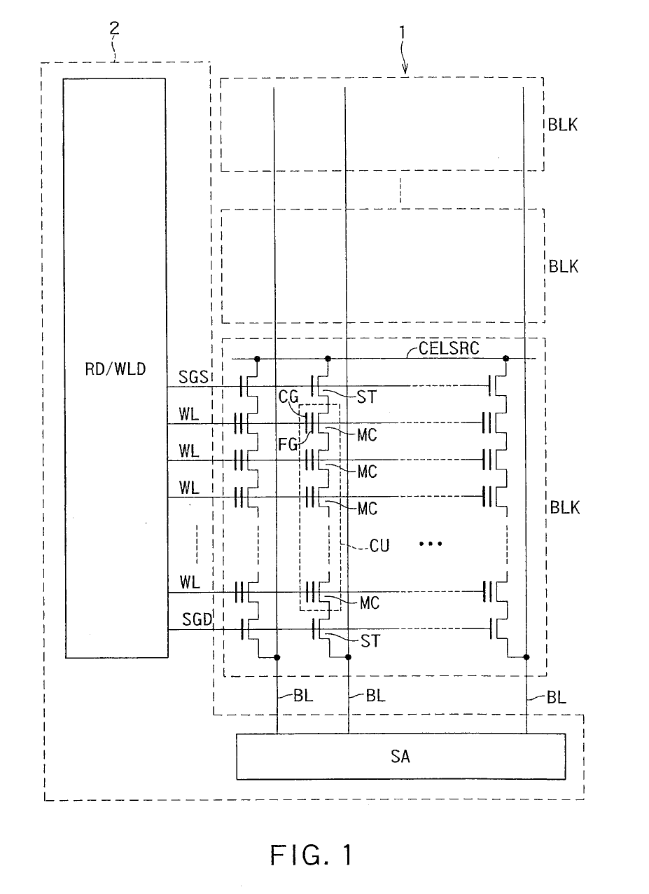

FIG. 1 shows a configuration of a semiconductor storage device according to a first embodiment.

The semiconductor storage device is a NAND flash memory (hereinafter, simply “memory”), for example. The memory includes a memory cell array 1 in which a plurality of memory cells MC are two-dimensionally arranged in a matrix and a peripheral circuit region 2 that controls the memory cell array 1.

The memory cell array 1 includes a plurality of blocks BLK. Each of the blocks BLK includes a plurality of memory cell units (hereinafter, simply “cell units”) CU. The block BLK is a unit of data deletion. The cell unit CU includes a plurality of memory cells MC serially connected to each other. Memory cells MC at ends of the cell unit CU are connected to selective transistors ST. The memory cell MC at one end is connected via a selective transistor ST to a bit line BL, and the memory cell MC at the other end is connected via a selective transistor ST to a cell source CELSRC.

Word lines WL are connected to control gates CG of the memory cells MC arranged in a row direction. Selective gate lines SGS and SGD are connected to gates of the selective transistors ST. The word lines WL and the selective gate lines SGS and SGD are driven by a row decoder and a word line driver WLD.

Each bit line BL is connected via the selective transistor ST to the cell unit CU. Each bit line BL is also connected to a sense amplifier circuit SA. Plural memory cells MC connected to a word line configure a page serving as a unit of reading and writing data at a time.

By driving the selective transistors ST by the selective gate lines SGS and SGD, the cell unit CU is connected between the bit line BL and the cell source CELSRC. Further, by driving unselected word lines WL by the word line driver WLD, memory cells MC other than a selected memory cell MC are turned on. Accordingly, the sense amplifier SA can apply a voltage to the selected memory cell MC via the bit line BL. In this way, the sense amplifier SA can detect data of the selected memory cell MC or write data in the selected memory cell MC.

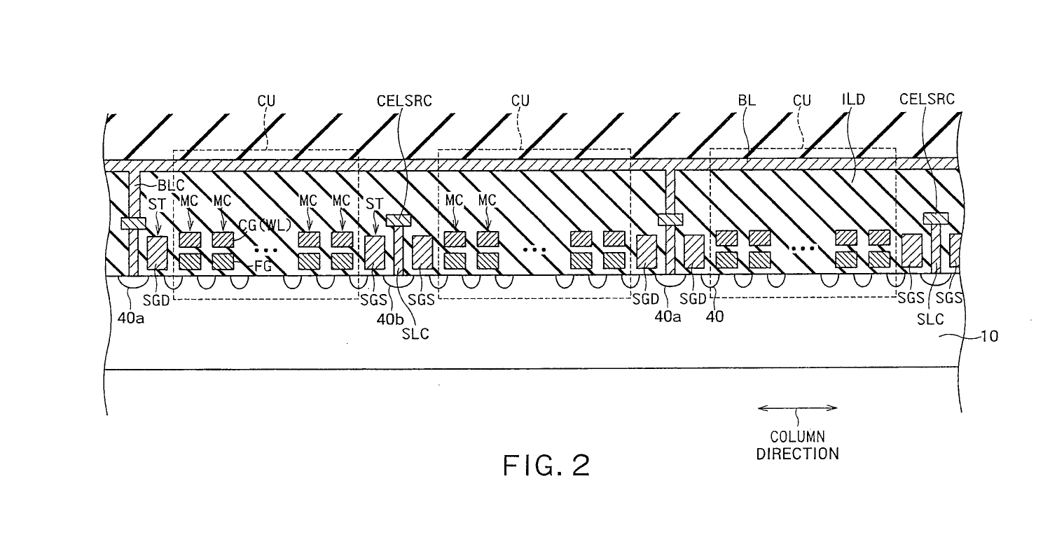

FIG. 2 is a cross-sectional view of a memory along an extending direction of the bit line BL. The memory cell MC and the selective transistor ST are formed on a semiconductor substrate 10. The cell unit CU indicated by a broken line frame includes plural memory cells MC serially connected to each other by a diffusion layer 40, for example.

The bit line BL is connected via a bit line contact BLC to a diffusion layer 40a of the selective transistor ST on a drain side. The cell source CELSRC is connected via a source line contact SLC to a diffusion layer 40b of the selective transistor ST on a source side.

The control gate CG that functions as the word line WL and the cell source CELSRC extend in a direction perpendicular to the bit line BL (a direction vertical to the diagram of FIG. 2 (a row direction)).

Plural cell units CU adjacent to each other in the extending direction of the bit line BL (a column direction) share either the bit line contact BLC or the source line contact SLC.

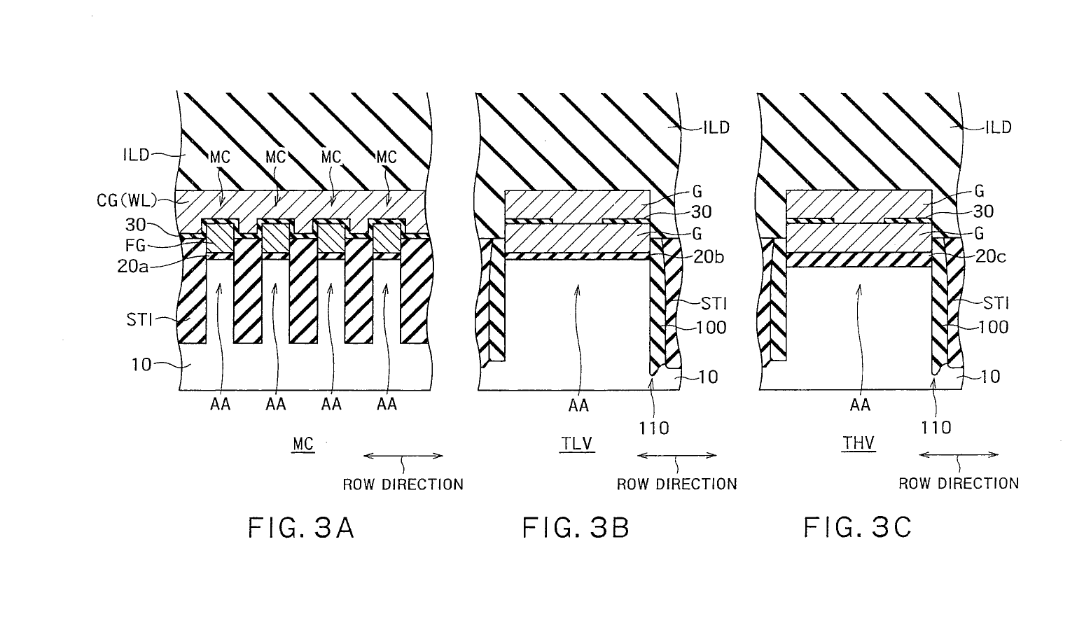

FIGS. 3A to 3C are cross-sectional views of a memory cell array region and a peripheral circuit region along an extending direction of the word line WL. FIG. 3A is a cross-sectional view of the memory cell MC, FIG. 3B is a cross-sectional view of a low-breakdown voltage transistor TLV in the peripheral circuit region, and FIG. 3C is a cross-sectional view of a high-breakdown voltage transistor THV in the peripheral circuit region.

As shown in FIG. 3A, the memory cells MC adjacent to each other in the extending direction of the word line WL (the row direction) are separated from each other by an element isolation part STI. This element isolation part STI is provided between active areas AA adjacent to each other in the row direction. This active areas AA extend in the column direction with the element isolation part STI and the memory cell MC is formed on a surface of the active areas AA.

Each of the memory cells MC includes the diffusion layer 40 (source/drain layer), a tunnel dielectric film 20a, a floating gate FG (charge trap layer), a gate dielectric film 30, and the control gate CG (the word line WL). As shown in FIG. 2, the diffusion layer 40 is formed on the surface of the active area AA of the semiconductor substrate 10. The tunnel dielectric film 20a is provided on the active area AA of the semiconductor substrate 10. The floating gate FG is provided on the tunnel dielectric film 20a and separated for each of the memory cells MC in the row direction and the column direction. The gate dielectric film 30 (IPD (Inter-Poly Dielectric)) is formed on top and side surfaces of the floating gate FG and separates the floating gate FG from the control gate CG. The control gate CG is provided upward and side of the floating gate FG with the gate dielectric film 30 interposed therebetween. The control gate CG extends in the row direction and is shared by plural memory cells MC included in the same page. In addition, the control gate CG also functions as the word line WL. An interlayer dielectric film ILD is provided on the control gate CG.

As shown in FIGS. 3B and 3C, the low-breakdown voltage transistor TLV and the high-breakdown voltage transistor THV in the peripheral circuit region are formed on the active area AA. Adjacent active areas AA are separated from each other by the element isolation part STI.

The low-breakdown voltage transistor TLV includes a gate dielectric film 20b and a gate electrode G. The gate dielectric film 20b is provided on the active area AA. The gate electrode G is provided on the gate dielectric film 20b. The gate dielectric film 30 is partially removed on a material for a floating gate. Therefore, the floating gate and the control gate are electrically connected to each other and integrally constitute the gate electrode G.

The low-breakdown voltage transistor TLV is different from the high-breakdown voltage transistor THV in the thickness of a gate dielectric film. A gate dielectric film 20c of the high-breakdown voltage transistor THV is formed in order to be thicker than the gate dielectric film 20b of the low-breakdown voltage transistor TLV. Other configurations of the high-breakdown voltage transistor THV can be nearly identical to those of the low-breakdown voltage transistor TLV.

As shown in FIGS. 3A to 3C, the element isolation part STI is provided between the active areas AA. An insulating film (for example, a silicon oxide film) is filled in a trench of the element isolation part STI. The insulating film in the element isolation part STI is filled in the trench by CVD and/or coating.

As shown in FIG. 3A, a sidewall film (a spacer) is not provided on an inner side surface of the trench of the element isolation part STI in the memory cell array region. That is, the sidewall film is not provided on the side surface of the active area AA in the memory cell array.

Meanwhile, as shown in FIGS. 3B and 3C, a sidewall film 100 (a spacer) is provided on the inner side surface of the trench of the element isolation part STI in the peripheral circuit region. That is, the sidewall film 100 is provided on the side surface of the active area AA in the peripheral circuit region.

The width of the element isolation part STI (the width between the active areas AA) in the memory cell array region is downscaled significantly and thus it is narrower than the width of the element isolation part STI (the width between the active areas AA) in the peripheral circuit region. Accordingly, the density of a planar layout of the element isolation part STI (the active area AA) in the memory cell array region is higher than that in the peripheral circuit region.

As explained above, when the density of the element isolation part STI and the active area AA in the memory cell array region is different from that in the peripheral circuit region, a difference in shape due to a density difference in planar layout or a micro-trench structure is generated in the memory cell array region and/or the peripheral circuit region. For example, the depth of the element isolation part STI in the peripheral circuit region with a low density of the element isolation part STI (the active area AA) is deeper than that in the memory cell array region and a micro-trench 110 is sometimes formed at a boundary between the active area AA and the element isolation part STI. The micro-trench 110 is a fine trench formed at a lower part of the side surface of the active area AA (an end of the element isolation part STI). When a CVD film and/or an organic coating film burying the element isolation part STI is filled in the entire STI including the micro-trench 110, the stress of the CVD film or organic coating film is applied to the micro-trench 110. This leads to defects of the active area AA or the element isolation part STI and the reliability of the entire memory may be deteriorated.

On the other hand, according to the first embodiment, the sidewall film 100 coats the side surface of the active area AA and is filled in the micro-trench 110 before the CVD film or the organic coating film is filled in the trench of the element isolation part STI. Because the micro-trench 110 is filled by the sidewall film 100 before the trench of the element isolation part STI is filled by the CVD film or the organic coating film, a stress caused by the CVD film or the organic coating film is not directly applied to the micro-trench 110. In the peripheral circuit region, the amount (volume) of the CVD film or the organic coating film filled in each element isolation part STI is reduced and a stress applied to the element isolation part STI in the peripheral circuit region is reduced. As a result, occurrences of defects of the active area AA or the element isolation part STI in the peripheral circuit region are suppressed, which leads to an improvement in the reliability of the entire memory.

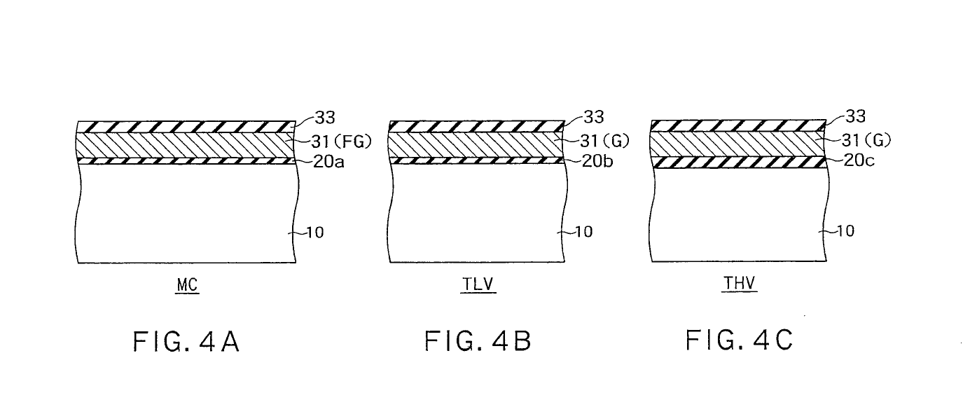

FIGS. 4 to 7 are cross-sectional views of a manufacturing method of a memory according to the first embodiment. FIGS. 4A, 5A, 6A, and 7A correspond to the cross-section of the memory cell array region shown in FIG. 3A, FIGS. 4B, 5B, 6B, and 7B correspond to the cross-section of the peripheral circuit region shown in FIG. 3B, and FIGS. 4C, 5C, 6C, and 7C correspond to the cross-section of the peripheral circuit region shown in FIG. 3C.

First, the tunnel dielectric film 20a and the gate dielectric films 20b and 20c are formed on the semiconductor substrate 10 (for example, a silicon substrate). For example, a silicon oxide film is used for the tunnel dielectric film 20a and the gate dielectric films 20b and 20c.

Next, a material 31 for the floating gate FG is deposited on the tunnel dielectric film 20a and the gate dielectric films 20b and 20c. For example, polysilicon is used for the material 31 for the floating gate FG. Next, a cap material 33 is deposited on the material 31 for the floating gate FG. For example, a silicon oxide film or a silicon nitride film is used for the cap material 33. Consequently, the configurations shown in FIGS. 4A to 4C can be obtained.

In the memory cell array region, the material 31 functions as the floating gate FG in a later process. Meanwhile, in the peripheral circuit region, the material 31 is electrically connected to the control gate CG in a later process, and thus functions as the gate electrode G of the transistors TLV and THV.

The cap material 33 serving as a mask material is processed in a pattern of the active area AA by lithography and RIE (Reactive Ion Etching). Alternatively, it is also possible that a mask material (not shown) different from the cap material 33 is deposited on the cap material 33 and then processed in the pattern of the active area AA.

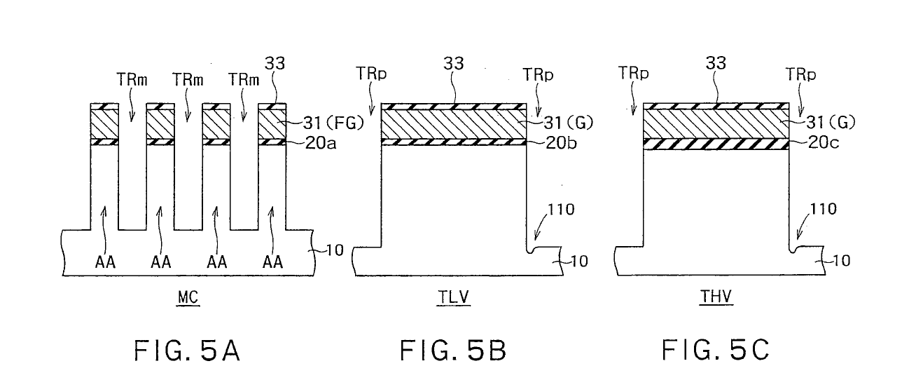

The material 31 for the floating gate FG, the tunnel dielectric film 20a, the gate dielectric films 20b and 20c, and the semiconductor substrate 10 are then etched by RIE by using the cap material 33 (or a mask material) as a mask. With this process, as shown in FIGS. 5A to 5C, trenches TRm and TRp are simultaneously formed in element isolation regions.

At this time, the micro-trench 110 is sometimes formed at an end of the trench TRp in the peripheral circuit region because of a density difference in the pattern of the active area AA between the memory cell array region and the peripheral circuit region.

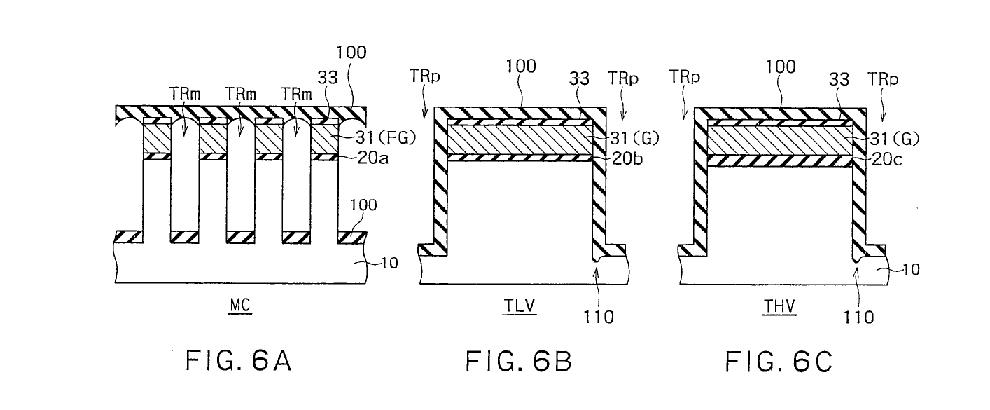

Therefore, as shown in FIGS. 6B and 6C, the insulating film 100 (a spacer dielectric film) is deposited by CVD in order to cover the inner side surface of the trench TRp in the peripheral circuit region. At this time, as shown in FIG. 6A, the spacer dielectric film 100 is deposited so as not to completely cover the inner side surface of the trench TRm in the memory cell array region, but to block an opening of the trench TRm.

Specifically, the spacer dielectric film 100 is deposited under inferior coverage conditions, so that the inner side surface of the trench TRm in the memory cell array region that the row direction width of the opening is narrow is not completely covered, and so that the inner side surface of the trench TRp in the peripheral circuit region that the row direction width of the opening is wide is covered. For example, to make the coverage inferior, the temperature of the semiconductor substrate 10 is reduced under high temperature or high pressure conditions at the time of applying CVD. With this process, the movement of deposited atoms is intentionally prevented after the atoms reach the semiconductor substrate 10 and supply of the deposited atoms is made to be in a rate-controlled state. In this way, in the trench TRm with a narrow opening, the opening is blocked by the spacer dielectric film 100 before the spacer dielectric film 100 is deposited thickly on the inner side surface. The spacer dielectric film 100 is deposited on the inner side surface of the trench TRp with a wide opening. As a result, the micro-trench 110 formed at the end of the trench TRp is filled by the spacer dielectric film 100.

For example, a silicon oxide film is used for the spacer dielectric film 100. The thickness of the spacer dielectric film 100 can be a thickness sufficient for burying the micro-trench 110. Because the size and depth of the micro-trench 110 are different depending on the pattern of a memory to be manufactured (the type of device), the depth of the trenches TRm and TRp, its manufacturing line and the like, they cannot be specifically determined. Accordingly, it suffices that the thickness of the spacer dielectric film 100 is set separately depending on the device to be manufactured and its manufacturing line.

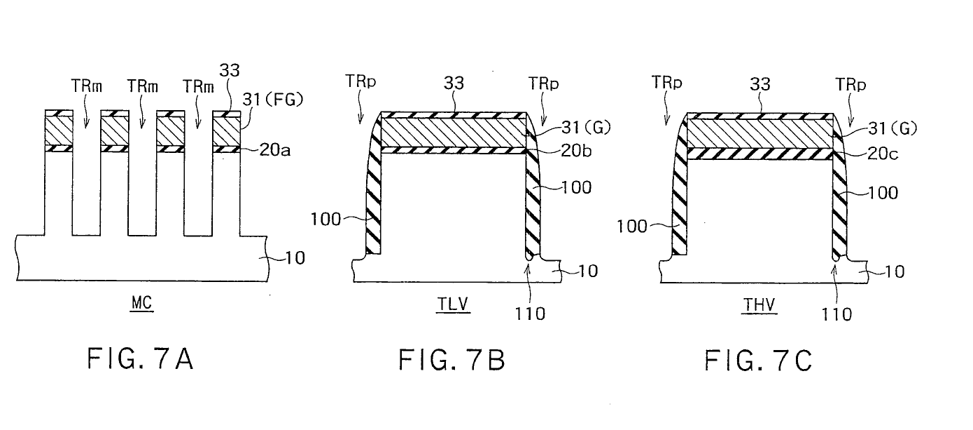

Next, the spacer dielectric film 100 is anisotropically etched by RIE, and then the spacer dielectric film 100 in the memory cell array region is removed while the spacer dielectric film 100 that covers the inner side surface of the trench TRp in the peripheral circuit region remains as a spacer. As shown in FIG. 7A, the spacer dielectric film 100 is removed from the memory cell array region. Meanwhile, as shown in FIGS. 7B and 7C, the spacer dielectric film 100 remains on the side surface of the active area AA in the peripheral circuit region, and the micro-trench 110 is maintained to be filled. In the following explanations, the spacer dielectric film 100 is also called as “sidewall film 100”.

When the spacer dielectric film 100 explained above is etched, the semiconductor substrate 10 at the bottom of the trench TRp is sometimes hollowed out, so that the bottom of the trench TRp is formed in a shape such that gouging has occurred. Because this shape smoothes the shape of the end of the element isolation part STI, it is useful for relaxing the stress of the insulating film filled in the element isolation part STI.

Because the material 31 for the floating gate FG is covered by the cap material 33, it is not damaged at the time of etching the spacer dielectric film 100.

Thereafter, the element isolation part STI is formed by known processes. For example, an insulating film is filled in the trenches TRm and TRp by LP-CVD (Low-Pressure CVD), CVD, and coating. Alternatively, the insulating film can be filled in the trenches TRm and TRp only by CVD and coating. Before filling the insulating film, a liner insulating film (not shown) can thinly cover the trenches TRm and TRp. The liner insulating film is formed by depositing a silicon oxide film by CVD, for example.

The element isolation part STI is etched back to remove the cap material 33. Thereafter, the gate dielectric film 30, the control gate CG, the diffusion layer 40, the interlayer dielectric film ILD, and a wiring are formed by known methods. Consequently, the memory shown in FIGS. 3A to 3C is completed.

According to the first embodiment, before an insulating film is filled in the trench TRp in the peripheral circuit region, the sidewall film 100 (a spacer) is filled in the micro-trench 110 formed in the trench TRp. The stress remaining on the sidewall film 100 is less than that of the insulating film filled in the trenches TRm and TRp. Therefore, the stress from the insulating film at the end of the element isolation part STI in the peripheral circuit region can be relaxed. This suppresses occurrences of defects at the end of the element isolation part STI and leads to an improvement in the reliability of the memory.

Furthermore, even when the micro-trench 110 is formed because of differences in the density of the layout pattern of the element isolation part STI (the active area AA) and in the depth of the element isolation part STI between the peripheral circuit region and the memory cell array region, the sidewall film 100 is filled in the micro-trench 110 in advance and occurrences of defects are thus suppressed. Therefore, according to the first embodiment, the layout pattern and the depth of the element isolation part STI can be arbitrarily set in the peripheral circuit region and the memory cell array region. For example, the depth of the element isolation part STI in the memory cell array region can be formed to a desired depth regardless of the micro-trench 110 of the element isolation part STI in the peripheral circuit region.

Further, the sidewall film 100 is provided in the trench TRp whose volume is relatively large in the peripheral circuit region, but is not provided in the trench TRm whose volume is relatively less in the memory cell array region. The difference between the volume of the insulating film filled in the trench TRp and thus the volume of the insulating film filled in the trench TRm is reduced. That is, the difference between the stress applied to the element isolation part STI in the peripheral circuit region and that applied to the element isolation part STI in the memory cell array region is reduced. This reduces the density difference of the element isolation part STI between the peripheral circuit region and the memory cell array region and enables these element isolation parts STI to be formed simultaneously.

### Second Embodiment

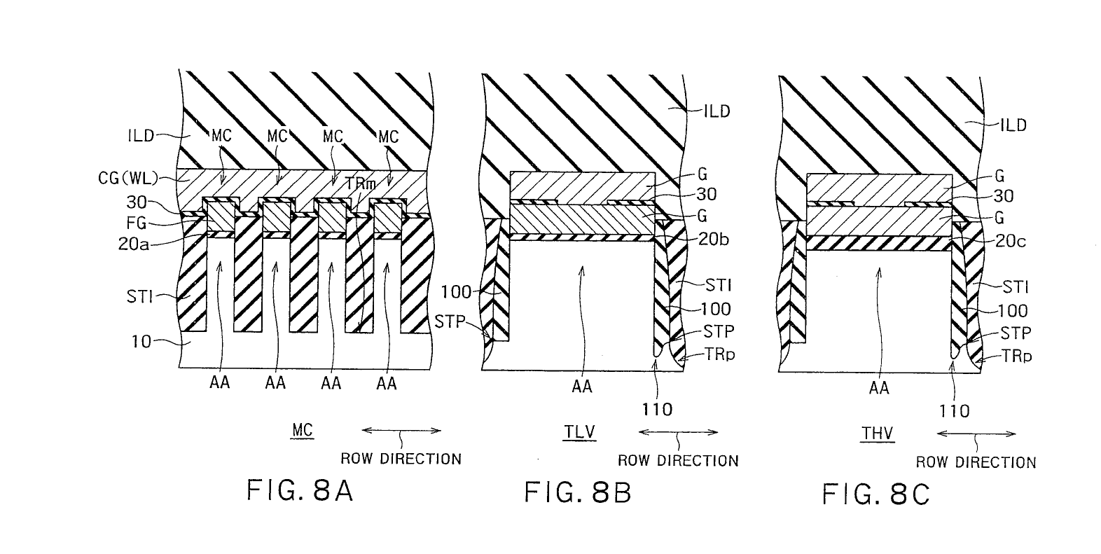

FIGS. 8A to 8C are cross-sectional views of a memory and a peripheral circuit region along an extending direction of the word line WL according to a second embodiment. FIG. 8A is a cross-sectional view of the memory cell MC, FIG. 8B is a cross-sectional view of the low-breakdown voltage transistor TLV in the peripheral circuit region, and FIG. 8C is a cross-sectional view of the high-breakdown voltage transistor THV in the peripheral circuit region.

According to the second embodiment, after the sidewall film 100 is filled in the micro-trench 110, the semiconductor substrate 10 is etched further to deepen the trenches TRp and TRm of the element isolation part STI. With this process, the depth of the element isolation part STI in the memory cell array region and the peripheral circuit region can be formed to a desired depth.

For example, in a case that the opening of the trench TRm in the memory cell array region is narrow and the opening of the trench TRp in the peripheral circuit region is wide, when the trenches TRm and TRp are formed simultaneously, the trench TRp in the peripheral circuit region is formed to be deeper than the trench TRm in the memory cell array region. In this case, the micro-trench 110 is easily formed in the trench TRp in the peripheral circuit region. To suppress forming of the micro-trench 110, it is conceivable that the trenches TRp and TRm are made shallow. However, in this case, the trench TRm in the memory cell array region may not be etched to a desired depth.

Therefore, according to the second embodiment, the sidewall film 100 is filled in the micro-trench 110 and then the semiconductor substrate 10 is etched again to deepen the trenches TRp and TRm of the element isolation part STI.

Accordingly, as shown in FIGS. 8B and 8C, the side surface of the active area AA in the peripheral circuit region has a step or concavity STP at the bottom of the sidewall film 100.

Furthermore, the element isolation part STI in the peripheral circuit region is formed to be deeper than the step or concavity STP at the bottom of the sidewall film 100. Meanwhile, as shown in FIG. 8A, the side surface of the active area AA in the memory cell array does not have a step or concavity.

Other configurations of the second embodiment can be identical to corresponding ones of the first embodiment.

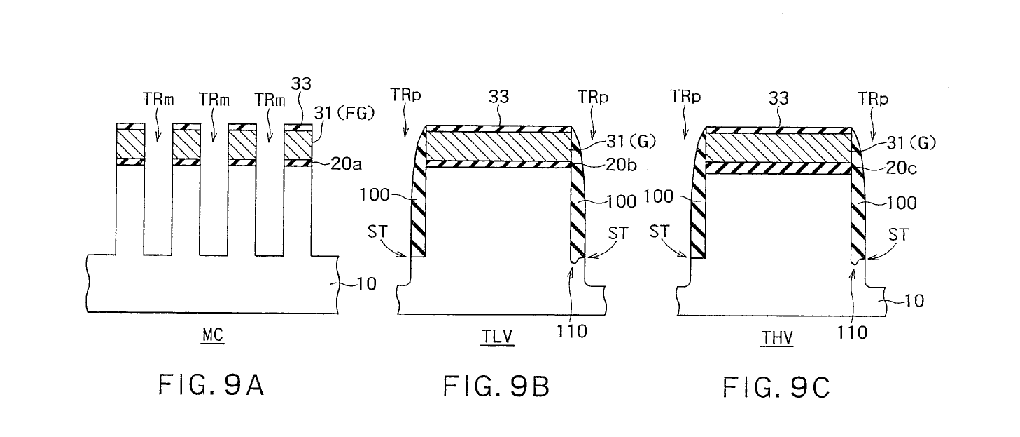

FIGS. 9A to 9C are cross-sectional views of a manufacturing method of a memory according to the second embodiment. After performing the manufacturing processes explained with reference to FIGS. 4 to 7, the semiconductor substrate 10 at the bottom of the trenches TRm and TRp is etched further. That is, after the spacer dielectric film 100 is filled in the micro-trench 110, the semiconductor substrate 10 is etched further for adjusting the depth of the trenches TRm and TRp.

Thereafter, the element isolation part STI is formed by known processes. For example, an insulating film is filled in the trenches TRm and TRp by LP-CVD (Low-Pressure CVD), CVD, and coating. Alternatively, the insulating film can be filled in the trenches TRm and TRp only by CVD and coating.

The element isolation part STI is etched back to remove the cap material 33. Thereafter, the gate dielectric film 30, the control gate CG, the diffusion layer 40, the interlayer dielectric film ILD, and a wiring are formed by known methods. Consequently, the memory shown in FIGS. 8A to 8C is completed.

The second embodiment has effects identical to those of the first embodiment. Furthermore, according to the second embodiment, the trenches TRm and TRp of the element isolation part STI are etched for plural times, that is, etched once or more respectively before and after forming the sidewall film 100. Therefore, even when the micro-trench 110 is formed in the element isolation part STI in the peripheral circuit region, the depth of the element isolation part STI in the memory cell array region and/or of the element isolation part STI in the peripheral circuit region can be formed to a desired depth while suppressing occurrences of defects of the element isolation part STI in the peripheral circuit region.

While the first and second embodiments explained above are embodiments related to a NAND flash memory, the above embodiments can be also applied to other devices having a density difference in the STI layout thereof.

While certain embodiments have been described, these embodiments have been presented by way of example only, and are not intended to limit the scope of the inventions. Indeed, the novel methods and systems described herein may be embodied in a variety of other forms; furthermore, various omissions, substitutions and changes in the form of the methods and systems described herein may be made without departing from the spirit of the inventions. The accompanying claims and their equivalents are intended to cover such forms or modifications as would fall within the scope and spirit of the inventions.

1. A semiconductor storage device comprising:
a memory cell array provided on a semiconductor substrate and comprising a plurality of memory cells configured to store data therein;
a peripheral circuit part provided on the semiconductor substrate and configured to control the memory cell array;
an element isolation part provided between active areas where the memory cells and the peripheral circuit part are formed; and
a sidewall film provided on a side surface of the active area in the peripheral circuit part.

2. The device of claim 1, wherein the sidewall film is buried in a fine trench at a lower part of a side surface of the active area in the peripheral circuit part.

3. The device of claim 1, wherein a side surface of the active area in the peripheral circuit part comprises a step or concavity at a bottom of the sidewall film.

4. The device of claim 2, wherein a side surface of the active area in the peripheral circuit part comprises a step or concavity at a bottom of the sidewall film.

5. The device of claim 3, wherein the element isolation part in the peripheral circuit part is formed to be deeper than a step or concavity at a bottom of the sidewall film.

6. The device of claim 1, wherein a distance between the element isolation parts adjacent to each other in the memory cell array is shorter than a distance between the element isolation parts adjacent to each other in the peripheral circuit part.

7. The device of claim 2, wherein a distance between the element isolation parts adjacent to each other in the memory cell array is shorter than a distance between the element isolation parts adjacent to each other in the peripheral circuit part.

8. The device of claim 3, wherein a distance between the element isolation parts adjacent to each other in the memory cell array is shorter than a distance between the element isolation parts adjacent to each other in the peripheral circuit part.

9. The device of claim 5, wherein a distance between the element isolation parts adjacent to each other in the memory cell array is shorter than a distance between the element isolation parts adjacent to each other in the peripheral circuit part.

10. A manufacturing method of a semiconductor storage device, the method comprising:
depositing a mask material above a semiconductor substrate;
processing the mask material into a pattern of an active area;
forming a trench by etching the semiconductor substrate by using the mask material as a mask;
depositing a spacer dielectric film in order to cover an inner side surface of the trench in a peripheral circuit part and to block an opening of the trench in the memory cell array which including a plurality of memory cells configured to store data therein;
by etching the spacer dielectric film, removing the spacer dielectric film in the memory cell array while the spacer dielectric film covering an inner side surface of the trench in the peripheral circuit part remains as a spacer; and
forming the element isolation part by filling an insulating film in the trench, wherein
the peripheral circuit part configured to control the memory cell array.

11. The method of claim 10, further comprising:
before depositing the mask material,
forming a gate dielectric film on the semiconductor substrate; and
depositing a gate electrode material on the gate dielectric film, and
after depositing the mask material on the gate electrode material,
processing the mask material in a pattern of the active area; and
forming the trench by etching the gate electrode material, the gate dielectric film, and the semiconductor substrate by using the mask material as a mask.

12. The method of claim 10, further comprising
after forming the spacer on an inner side surface of the trench in the peripheral circuit part,
adjusting a depth of the trench by etching the semiconductor substrate further.

13. The method of claim 11, further comprising
after forming the spacer on an inner side surface of the trench in the peripheral circuit part,
adjusting a depth of the trench by etching the semiconductor substrate further.
